(19) United States
(12) Patent Application Publication
(10) Pub. No.: US 2021/0057881 A1
(43) Pub. Date: Feb. 25, 2021

(54) VERTICAL-CAVITY SURFACE-EMITTING LASER

(71) Applicant: BrightIntelligence Technologies (Zhongshan) Co., Ltd., Guandong (CN)

(72) Inventors: Michael C. Y. CHAN, Guangdong (CN); Yuhui LUO, Guangdong (CN)

(73) Assignee: BrightIntelligence Technologies (Zhongshan) Co., Ltd., Guangdong (CN)

(21) Appl. No.: 16/967,139

(22) PCT Filed: Dec. 7, 2018
(86) PCT No.: PCT/CN2018/119796

§ 371 Date: Aug. 4, 2020

(30) Foreign Application Priority Data
Dec. 5, 2018 (CN) 201811477564.9

(51) Int. Cl. H01S 5/183; H01S 5/042

(52) U.S. Cl. CPC H01S 5/18311; H01S 5/04257; H01S 5/18377; H01S 5/18358

(57) ABSTRACT

A vertical-cavity surface-emitting laser, comprising a substrate, wherein bottom n-type DBR mirror, first oxidation confinement layer, n-type guide spacer layer, active region layer, p-type guide spacer layer, second oxidation confinement layer, first spacer layer, third oxidation confinement layer second spacer layer, fourth oxidation confinement layer, third spacer layer, fifth oxidation confinement layer, fourth spacer layer, sixth oxidation confinement layer, fifth spacer layer, seventh oxidation confinement layer, sixth spacer layer, eighth oxidation confinement layer, top p-type DBR mirror, p-type contact layer and p-side electrode are successively stacked on the substrate; and a back surface of the substrate is provided with an n-side electrode.

### BACKGROUND

### Technical Field

The present disclosure relates to a vertical cavity surface emitting laser, and more particularly to a high-power single mode vertical cavity surface emitting laser having a DBR mirror having a plurality of current confinement layers.

### Description of Related Art

There are several effective methods of current confinement and lateral optical confinement in high power single mode VCSELs (Vertical Cavity Surface Emitting Lasers), of which the more commonly used methods are buried heterostructures, etched air-post, ion implantation, and selective oxidation. In particular, the adopted oxide-confined VCSELs exhibit superior performance in terms of modulation bandwidth due to effective current and optical confinement in a small effective volume. The oxidation confinement layer within the VCSEL has been used to minimize power dissipation by confining a current within the lasing modes and guiding laser. However, these oxidation confinement layers produce undesirable optical scattering due to the imperfect shape of their epitaxial semiconductors and require a larger mode diameter to achieve low optical losses.

The VCSEL structure having a plurality of oxidation confinement layers in the top p-type DBR mirror is composed of two parts; one is a current confinement layer and the other is an optical confinement layer. Current confinement is desirable for VCSELs in which electrical current is used to provide a means for pumping the active region to achieve gain. In VCSEL, for example, top and bottom electrical contacts are typically provided above and below the active area to apply pumping current through the active region. The current confinement method limits the pumping current into a relatively small area of the active region by setting a current confinement structure. These include simple mesa etching of the top p-type DBR mirror or selective lateral oxidation of high aluminum content, such as Al_{0.98}Ga_{0.02}As or even AlAs placed at between the node and/or antinode of the optical standing wave near the active layer, and its thickness is usually between 20 nm and 30 nm.

The optical confinement layer is formed as the same current confinement layer and/or as an alternative oxidation confinement layer in pairs of DBR mirrors above the current confinement layer. In these typical VCSEL structures, the optical confinement layer is designed to have a larger oxide aperture of about 1-3 μm than the current confinement layer, and both the active region and the oxide aperture are located at the antinode of the optical standing wave. Therefore, these VCSELs operate as index-guided devices with strong radial built-in refractive index confinement, which are advantageous for higher order transverse modes for broader than 6 μm optical aperture in the oxidation confinement layer. These typical VCSEL structures cannot guarantee the fundamental mode operation.

Although the scattering loss of fundamental mode can be suppressed to the same level of typical VCSEL, the multiple oxidation layers produce a larger scattering loss and suppress higher order transverse modes than typical VCSELs. The optical mode distribution of the higher order transverse mode is wider than the fundamental mode. If the aperture size of the optical confinement layer is designed to be wider than the profile of the fundamental mode and smaller than that of the high-order transverse mode, then only the high-order transverse mode suffers larger optical loss due to scattering of the optical confinement layer.

The scattering loss of VCSEL depends on the location of the oxidation confinement layer within the VCSEL cavity. When the oxidation confinement layer is located at a node in the optical standing wave, there is no aperture dependent loss. However, when the oxidation confinement layer is located at the antinode, the scattering loss is clearly a function of the aperture size. As the aperture size increases to a size of >6 μm, the scattering losses begin to merge. For large aperture multi-mode VCSELs, the placement of the oxidation confinement layer does not contribute to scattering losses. However, for small aperture single-mode VCSELs, the scattering loss can be reduced to a negligible level by placing aperture at the nodes in the optical standing wave.

The Al fraction of the AlGaAs layers used for the first several top p-type DBR mirrors is increased from 94% to 96% to form an oxidation confinement layer. When oxidizing the aperture layers, these high aluminum content layers oxidized relatively faster than other DBR periods forming thicker dielectric layers in the perimeter of the mesa. These oxidized layers effectively increase the equivalent capacitor thickness and reduce parasitic capacitance. It is effective to increase the total thickness of the plurality of oxidation confinement layers to achieve low parasitic capacitance of the device.

An oxide-confined VCSEL devices are typically effective as a laser source. However, the oxidation confinement structure can be improved. For example, an oxide-confined VCSEL device has a current confinement layer placed directly above the top of the active region. The parasitic capacitance is reduced and a high frequency with low power consumption is achieved by appropriately designing different numbers of oxide aperture layers.

### SUMMARY

In order to solve the above problems in the prior art, it is an object of the present disclosure to provide a vertical cavity surface emitting laser. The present disclosure is capable of stably achieving single mode operation and has the advantages of low optical loss, low power consumption, and low parasitic capacitance.

A vertical cavity surface emitting laser according to the present disclosure comprises a base on which a substrate, a bottom n-type DBR mirror, a first oxidation confinement layer, an n-type guide spacer layer, an active region layer, a p-type gradational spacer layer, a second oxidation confinement layer, a first spacer layer, a third oxidation confinement layer, a second spacer layer, a fourth oxidation confinement layer, a third spacer layer, a fifth oxidation confinement layer, a fourth spacer layer, a sixth oxidation confinement layer, a fifth spacer layer, a seventh oxidation confinement layer, a sixth spacer layer, an eighth oxidation confinement layer, a top p-type DBR mirror, a p-type contact layer, and a p-side electrode; an n-side electrode is disposed on a back surface of the base far from the substrate.

The bottom n-type DBR mirror includes a plurality of first refractive index layers and a plurality of second refractive index layers, wherein a first refractive index layer and a second refractive index layer are both AlGaAs layers, and the refractive index of a first refractive index layer is lower than that of the second refractive index layer.

The active region layer is disposed in an antinode region of a standing optical wave formed by a vertical cavity surface emitting laser, the active region layer includes a plurality of quantum well layers, and the quantum well layer is an InAlGaAs layer.

The first oxidation confinement layer is provided with a first current injection region with the aperture opening diameter ranging from 9 to 14 μm, and the first oxidation confinement layer is placed at the node of the optical standing wave formed by the vertical cavity surface emitting laser.

The second oxidation confinement layer is provided with a second current injection region, the diameter of the second current injection region is equal to the diameter of the first current injection region, and the second oxidation confinement layer is placed at the node of the optical standing wave formed by the vertical cavity surface emitting laser.

The third oxidation confinement layer is provided with a third current injection region, the diameter of the third current injection region is smaller than the diameter of the second current injection region of 6-9 μm, and the third oxidation confinement layer is placed at the node of the optical standing wave formed by the vertical cavity surface emitting laser.

The fourth oxidation confinement layer is provided with a fourth current injection region, the diameter of the fourth current injection region is equal to the diameter of the third current injection region, and the fourth oxidation confinement layer is placed at the node of the optical standing wave formed by the vertical cavity surface emitting laser.

The fifth oxidation confinement layer is provided with a fifth current injection region, the fifth current injection region has a diameter ranging from 14 to 20 μm, and the fifth oxidation confinement layer is placed at the node of the optical standing wave formed by the vertical cavity surface emitting laser.

The sixth oxidation confinement layer is provided with a sixth current injection region, the sixth current injection region has a diameter ranging from 14 to 20 μm, and the sixth oxidation confinement layer is placed at the node of the optical standing wave formed by the vertical cavity surface emitting laser.

The seventh oxidation confinement layer is provided with a seventh current injection region, the seventh current injection region has a diameter ranging from 14 to 20 μm, and the seventh oxidation confinement layer is placed at the node of the optical standing wave formed by the vertical cavity surface emitting laser.

The eighth oxidation confinement layer is provided with an eighth current injection region, the eighth current injection region has a diameter ranging from 14 to 20 μm, and the eighth oxidation confinement layer is placed at the node of the optical standing wave formed by the vertical cavity surface emitting laser.

The top p-type DBR mirror includes a plurality of third refractive index layers and a plurality of fourth refractive index layers, wherein the third refractive index layer and the fourth refractive index layer are all AlGaAs layers. The refractive index of the third refractive index layer is lower than that of the fourth refractive index layer.

Also, the vertical cavity surface emitting laser includes a mesa structure extending from the top p-type DBR mirror to the bottom n-type DBR mirror, a dielectric coating layer being provided on at least a portion of the side of the mesa structure.

Preferably, in at least one of the first oxidation confinement layer, the second oxidation confinement layer, the third oxidation confinement layer, the fourth oxidation confinement layer, the fifth oxidation confinement layer, the sixth oxidation confinement layer, the seventh oxidation confinement layer, and the eighth oxidation confinement layer is provided with a first annular oxidation injection region provided with the current confinement layer for confining the current flowing in the active region.

Preferably, in at least one of the first oxidation confinement layer, the second oxidation confinement layer, the third oxidation confinement layer, the fourth oxidation confinement layer, the fifth oxidation confinement layer, the sixth oxidation confinement layer, the seventh oxidation confinement layer, and the eighth oxidation confinement layer is provided with a first annular oxidation confinement region provided with the optical confinement layer for confining light generated in the active region.

Preferably, in at least four of the first oxidation confinement layer, the second oxidation confinement layer, the third oxidation confinement layer, the fourth oxidation confinement layer, the fifth oxidation confinement layer, the sixth oxidation confinement layer, the seventh oxidation confinement layer, and the eighth oxidation confinement layer are provided with a second annular oxidation confinement region, and the second annular oxidation confinement region is provided with an oxide aperture.

Preferably, the annular oxidation injection region, the first annular oxidation confinement region, and the second annular oxidation confinement region are oxidized AlGaAs layers having a composition of from 0.94 to 0.98.

Preferably, the base is a grid base.

Preferably, a buffer layer is provided between the substrate and the bottom n-type DBR mirror.

Preferably, the p-side electrode is a ring electrode.

Preferably, the bottom n-type DBR mirror, the active region layer and the top p-type DBR mirror are a molecular beam epitaxial layer or a metal organic chemical vapor deposition deposited layer.

The vertical cavity surface emitting laser of the present disclosure has the advantages that the multiple oxidation confinement layers are disposed at the node of the optical standing wave to ensure that the vertical cavity surface emitting laser performs single mode operation. The structure of the top p-type DBR mirror and the bottom n-type DBR mirror can reduce the resistance of the present disclosure and reduce power consumption. The structure of the oxidation confinement layer can effectively reduce the parasitic capacitance of the present disclosure, increase the thickness of the oxide layer to reduce the oxide capacitance, and speed up the modulation speed of the present disclosure. The carrier distribution is more closely matched to the fundamental transverse mode of VCSEL by using multiple oxidation confinement layers on both sides of the active region and optimizing the oxidation confinement layers. At the same time, single mode operation is ensured.

### BRIEF DESCRIPTION OF THE DRAWINGS

FIG. 1 shows a cross sectional structure of a VCSEL according to a first example of the disclosure.

FIG. 2 show a cross sectional structure of a VCSEL according to a second example of the disclosure.

FIG. 3 show a cross sectional structure of a VCSEL according to a third example of the disclosure.

### DESCRIPTION OF REFERENCE NUMERALS: 100—base, 101—substrate, 102—bottom

n-type DBR mirror, 104—first oxidation confinement layer, 105—n-type guide spacer layer, 106—active layer, 107—p type gradational spacer layer, 108—second oxidation confinement layer, 109—first spacer layer, 110—third oxidation confinement layer, 111—second spacer layer, 112—fourth oxidation confinement layer, 113—third spacer layer, 114—fifth oxidation confinement layer, 115—fourth spacer layer, 116—sixth oxidation confinement layer, 117—fifth spacer layer, 118—seventh oxidation confinement layer, 119—sixth spacer layer, 120—eighth oxidation confinement layer, 121—top p-type DBR mirror, 122—p contact layer, 123—p side electrode, 130—mesa structure, a-the node of the optical standing wave, b-the antinode of the optical standing wave, c-intensity of the optical standing wave.

### DESCRIPTION OF THE EMBODIMENTS

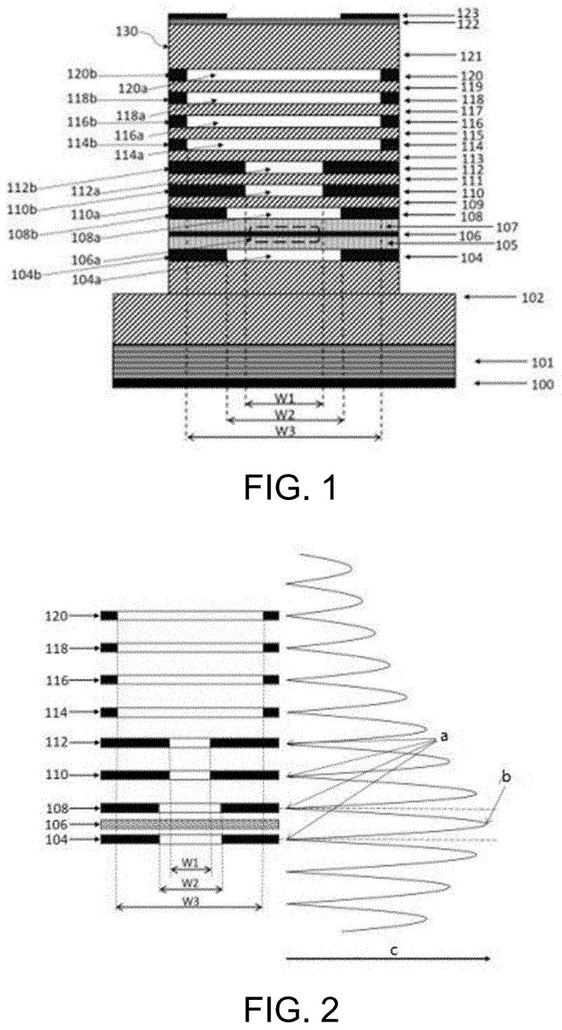

As shown in FIGS. 1 to 3, a vertical cavity surface emitting laser according to the present disclosure will be described in detail with reference to the accompanying drawings.

FIG. 1 shows a cross sectional structure of a VCSEL according to an embodiment of the present disclosure. FIG. 2 shows an enlarged cross section of a first oxidation confinement layer 104, a second oxidation confinement layer 108, a third oxidation confinement layer 110, a fourth oxidation confinement layer 112, a fifth oxidation confinement layer 114, a sixth oxidation confinement layer 116, a seventh oxidation confinement layer 118, and an eighth oxidation confinement layer 120 of the VCSEL of FIG. 1 and the vicinity thereof, FIG. 2 also shows intensity of optical standing wave of the first oxidation confinement layer 104, the second oxidation confinement layer 108, the third oxidation confinement layer 110, the fourth oxidation confinement layer 112, the fifth oxidation confinement layer 114, the sixth oxidation confinement layer 116, the seventh oxidation confinement layer 118, and the eighth oxidation confinement layer 120 of the VCSEL of FIG. 1 and the vicinity thereof. FIG. 2 shows the views as a model, and thus the dimensions and the shapes thereof are different from actual dimensions and shapes.

The VCSEL includes a cavity, wherein the bottom n-type DBR mirror 102, the first oxidation confinement layer 104, the n-type guide spacer layer 105, the active region layer 106, the p-type gradational spacer layer 107, the second oxidation confinement layer 108, the first spacer layer 109, the third oxidation confinement layer 110, the second spacer layer 111, the fourth oxidation confinement layer 112, the third spacer layer 113, the fifth oxidation confinement layer 114, the fourth spacer layer 115, the sixth oxidation confinement layer 116, the fifth spacer layer 117, the seventh oxidation confinement layer 118, the sixth spacer layer 119, the eighth oxidation confinement layer 120, the top p-type DBR mirror 121, the p-type contact layer 122, and the p-side electrode 123 are formed in this order on one surface of a substrate 101.

An upper portion of the bottom n-type DBR mirror 102 where the first oxidation confinement layer 104, the n-type guide spacer layer 105, the active region layer 106, the p-type gradational spacer layer 107, the second oxidation confinement layer 108, the first spacer layer 109, the third oxidation confinement layer 110, the second spacer layer 111, the fourth oxidation confinement layer 112, the third spacer layer 113, the fifth oxidation confinement layer 114, the fourth spacer layer 115, the sixth oxidation confinement layer 116, the fifth spacer layer 117, the seventh oxidation confinement layer 118, the sixth spacer layer 119, the eighth oxidation confinement layer 120, the top p-type DBR mirror 121 and the p-type contact layer 122 are located, and then selectively etching the top surface of the p-type contact layer 122, and thus becomes a columnar mesa structure 130. The p-side electrode 123 is formed on the p-type contact layer 122, and the p-side electrode 123 and the n-side electrode 100 are formed on the back surface of the substrate 101.

The first oxidation confinement layer 104 is placed about n/4 below the active region layer 106, and the second oxidation confinement layer 108 is placed about n/4 above the active region layer 106.

The substrate, the bottom n-type DBR mirror 102, the first current injection region 104a, the n-type guide spacer layer 105, the active region layer 106, the p-type gradational spacer layer 107, the second current injection region 108a, and the third current injection region 110a The fourth current injection region 112a, the fifth extremely large current injection region 114a, the sixth current injection region 116a, the seventh current injection region 118a, the eighth current injection region 120a and the p-type contact layer 122 are respectively made of, for example, a GaAs-based compound semiconductor. The GaAs-based compound semiconductor includes a compound semiconductor containing at least gallium (Ga) of group III elements and at lease arsenic (As) of group V elements in the short cycle of periodic table.

The base 100 is made of, for example, n-type GaAs. The bottom n-type DBR mirror layer 102 includes a plurality of sets of first refractive index layers and second refractive index layers, for example, as on set. The first refractive index layer is formed of n-type AlGaAs having a thickness of λ/(4nₐ) (λ represents an oscillation wavelength and nₐ represents a refractive index). The second refractive index layer is formed of n-type AlGaAs having a thickness of λ/(4n_{b}) (n_{b} is a refractive index). Examples of the n-type impurity include silicon (Si), selenium (Se), and the like can be cited. The refractive index of the first refractive index layer is lower than that of the second refractive index layer.

The n-type guide spacer layer 105 is made of, for example, AlGaAs. The active region 106 is made of, for example, a GaAs-based material. In the active region layer 106, a region opposed to the current injection region is a light-emitting region, and a central region of the light-emitting region 106A is a region that mainly generates fundamental transverse mode oscillation and surrounds the light-emitting central region of the light-emitting region 106A is a region that mainly generates high-order transverse mode oscillation. The p-type guide spacer layer 107 is made of, for example, AlGaAs. Although the n-type guide spacer layer 105, the active region 106 and the p-type guided layer 107 are desirably free of impurities, they may contain p-type impurities or n-type impurities.

Each spacer layer is made of, for example, p-type AlGaAs. For example, the top p-type DBR mirror 121 includes a plurality of sets of third refractive index layers and fourth refractive index layers, which are considered as one set. For example, the third refractive index layer is formed of p-type AlGaAs (0<x6<1), and its thickness is a refractive index λ/(4n_{c}) (λ is an oscillation wavelength, and n_{c} is a refractive index). The fourth refractive index layer is formed of p-type AlGaAs and has a thickness of λ/(4n_{d}) (n_{d} is a refractive index) thickness. Examples of the p-type impurity include zinc (Zn), magnesium (Mg), and beryllium (Be) or the like can be cited.

The first oxidation confinement layer 104 as a current confinement layer has a ring-shaped of the first current confinement region 104b in its outer edge region thereof. The first oxidation confinement layer 104 has an annular first current injection region 104a (first current injection region) having a diameter of W2 (for example, 9 to 14 μm) in its central region thereof. The first current injection region 104a is made of, for example, AlGaAs (0.98<x<1). The first current confinement region 104b includes Al₂O₃ (aluminum oxide) obtained by oxidizing a high concentration of Al contained in the first oxidation confinement layer 104 from a side surface of the mesa structure 130. That is, the first oxidation confinement layer 104 has a function of current confinement.

The second oxidation confinement layer 108 as a current confinement layer has a ring-shaped of the second current confinement region 108b in its outer edge region thereof. The second oxidation confinement layer 108 has an annular second current injection region 108a (second current injection region) having a diameter of W2 (for example, 10 to 15 μm) in its central region thereof. The second current injection region 108a is made of, for example, AlGaAs (0.97<x<0.99). The second current confinement region 108 includes Al₂O₃ (aluminum oxide) obtained by oxidizing a high concentration of Al contained in the second current confinement layer 108 from a side surface of the mesa 130. That is, the second oxidation confinement layer 108 has a function of confining current.

The first oxidation confinement layer 104 and the second oxidation confinement layer 108 are formed at a region including a node located apart from an antinode in the active region layer 106 by λ/2 (λ is the resonance wavelength). For example, as shown in FIG. 2, the first oxidation confinement layer 104 is formed at a region between the active region layer 106 and the bottom n-type DBR layer 102. The second oxidation confinement layer 108 is formed at a region between the active region layer 106 and the active region 106.

When the layer containing the oxide is located at the node of the optical standing wave, the light passing through the cavity is not scattered by the layer containing the oxide. The layer containing the oxide is transparent for the light passing through the cavity. Therefore, the first current confinement region 104b and the second current confinement region 108b ideally have characteristics not to give a loss to the light passing through the cavity and not to suppress oscillation.

The third oxidation confinement layer 110 and the fourth oxidation confinement layer 112 have a function to confine a current more efficiently compared to the first oxidation confinement layer 104 and the second oxidation confinement layer 108. Therefore, the diameter of the first current injection region 104a and the second current injection region 108a can be relatively freely set. When the diameters of the first current injection region 104a and the second current injection region 108a are adjusted to an appropriate value (for example, 10 to 15 μm), the light in the central portion of fundamental transverse mode in the light-emitting region 106a is hardly lost, and a large gain in the outer edge of the light-emitting region 106a selectively give a loss. As described above, in addition to the function of confinement current, the first oxidation limiting layer 104 and the second oxidation confinement layer 108 also have a function of selectively providing the loss only to light in the high-order transverse mode.

In addition, even when the diameters of the first current injection region 104a and the second current injection region 108a are not relatively small, the third oxidation confinement layer 110 and the fourth oxidation confinement layer 112 can also suppress a high order transverse mode. Therefore, the diameters of the first current injection region 104a and the second current injection region 108a can be increased. When the diameters of the first current injection region 104a and the second current injection region 108a increase, the area of the light-emitting region 106a increases. Therefore, the resistance (junction resistance) of the active layer 106 is reduced, and the series resistance and electric power consumption of the VCSEL can be reduced.

The third oxidation confinement layer 110 and the fourth oxidation confinement layer 112 have a ring-shaped of the third current confinement region 110b and the fourth current confinement region 112b in the outer edge region. The third oxidation confinement layer 110 and the fourth oxidation confinement layer 112 have an annular third current injection region 110a and an annular fourth current injection region 112a having a diameter W1 (for example, 6 to 9 μm) in a central portion thereof. W1 is smaller than W2. The third current injection region 110a and the fourth current injection region 112a are made of, for example, AlₓGa₁₋ₓAs (0.98<x<1). The third current confinement region 110b and the fourth current confinement region 112b include Al₂O₃ (aluminum oxide) obtained by oxidizing the high concentration Al contained in the third oxidation confinement layer 110 and the fourth oxidation confinement layer 112 from the side surface of the mesa 130. As shown in figures, the third oxidation confinement layer 110 and the fourth oxidation confinement layer 112 have a function to confine a current more strongly compared to the first oxidation confinement layer 104 and the second oxidation confinement layer 108.

The third oxidation confinement layer 110 and the fourth oxidation confinement layer 112 are formed at regions including nodes separated from the antinodes in the active region layer 106, which are (3λ)/4 and (5λ)/4, respectively. For example, as shown in FIG. 2, the third oxidation confinement layer 110 is formed in a region between the second oxidation confinement layer 108 and the fourth oxidation confinement layer 112. The fourth oxidation confinement layer 112 is formed at a region between the third oxidation confinement layer 110 and the third spacer layer 113.

When the layer containing the oxide is located at the node of the optical standing wave, the light passing through the cavity is not scattered by the layer containing the oxide. The layer containing the oxide is transparent to light penetration in the cavity. Therefore, the third current confinement region 110b and the fourth current confinement region 112b desirably have characteristics that do not impair the light passing through the cavity and do not suppress the oscillation. However, the third current confinement region 110b and the fourth current confinement region 112b have a certain thickness and occupy a portion other than the node of the optical standing wave. Therefore, the loss of light is slightly generated.

The first oxidation confinement layer 104 and the second oxidation confinement layer 108 are not arranged adjacent to physically contact each other. The third oxidation confinement layer 110 and the fourth oxidation confinement layer 112 are also arranged adjacent to physically contact each other. If the first oxidation confinement layer 104, the second oxidation confinement layer 108, the third oxidation confinement layer 110, and the fourth oxidation confinement layer 112 are in contact with each other, the first and second oxidation confinement layers and the third and fourth oxidation confinement layers are formed the thick oxidation confinement layer in the cavity, resulting in the possibility of blocking the amplitude function of the cavity. If the amplitude function of the cavity is lost, not only the oscillation in the high-order transverse mode but also the oscillation in the fundamental transverse mode is suppressed, so it is difficult to selectively suppress only the high-order transverse mode oscillation.

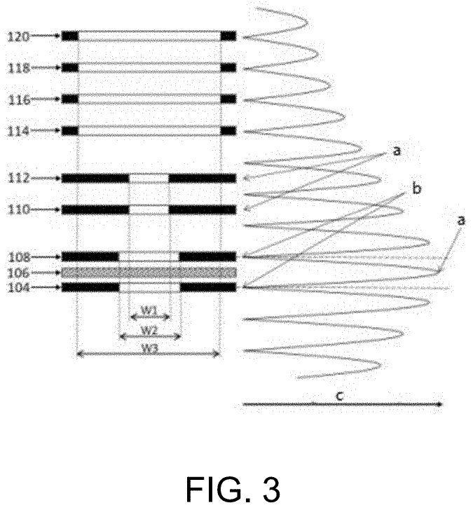

The third oxidation confinement layer 110 and the fourth oxidation confinement layer 112 are formed in regions including the antinodes separated from the antinodes in the active region layer 106, respectively λ and (3λ)/2. For example, as shown in FIG. 3, the third oxidation confinement layer 110 is formed in a region between the second oxidation confinement layer 108 and the fourth oxidation confinement layer 112. The fourth oxidation confinement layer 112 is formed at a region between the third oxidation confinement layer 110 and the third spacer layer.

When the oxidation confinement layer is located at the antinode of the optical standing wave, the light in the cavity is scattered passing through the layer containing the oxide. Therefore, the third current confinement region 110b and the fourth current confinement region 112b basically have a characteristic to give a loss to the light passing through the cavity and suppress the oscillation. However, the third current confinement region 110b and the fourth current confinement region 112b are formed only in the outer edge regions of the third oxidation confinement layer 110 and the fourth oxidation confinement layer 112, respectively. Therefore, the third current confinement region 110b and the fourth current confinement region 112b mainly suppress the oscillation in the transverse mode, in which there is a large gain in the region corresponding to the outer edge region of the third oxidation confinement layer 110 and the fourth oxidation confinement layer 112 (the outer edge of the light emitting region) out of the light passing through the cavity. That is, the third current confinement region 110b and the fourth current confinement region 112b hardly suppresses oscillation in the transverse mode with the order having a large gain in the region corresponding to the third current injection region 110a and the fourth current injection region 112a (central portion of the light emitting region) out of the light passing through the cavity. Thus, for the light in these transverse modes, the third oxidation confinement layer 110 and the fourth oxidation confinement layer 112 are almost transparent.

Since the third current injection region 110a and the fourth current injection region 112a are disposed at the central portions of the third oxidation confinement layer 110 and the fourth oxidation confinement layer 112, the third oxidation confinement layer 110 and the fourth oxidation confinement layer 112 have a function to confirm the current. Therefore, the diameters of the third current injection region 110a and the fourth current injection region 112a can be reduced to a current density which is almost uniform over the entire region of the third current injection region 110a and the fourth current injection region 112a without a substantial loss of light source. As described above, in the third oxidation confinement layer 110 and the fourth oxidation confinement layer 112, the diameter of the third current injection region 110a and the fourth current injection region 112a can be relatively freely set.

Further, the third oxidation confinement layer 110 and the fourth oxidation confinement layer 112 are disposed at positions farther from the active region 106 than the first oxidation confinement layer 104 and the second oxidation confinement layer 108. Therefore, the third current injection region 110a and the fourth current injection region 112a are set to the size with which the current density becomes almost uniform over the whole area of the third current injection region 110a and the fourth current injection region 112a, the current confined by the third oxidation confinement layer 110 and the fourth oxidation confinement layer 112 are not concentrated on the outer edge of the first current injection region 104a of the first oxidation confinement layer 104 and the outer edge of the second current injection region 108a of the second oxidation confinement layer 108, and the current is concentrated on the central portion of the first current injection region 104a and the second current injection region 108a. As a result, current can be collectively injected into the central portion of the active region layer 106 corresponding to the first current injection region 104a and the second current injection region 108a (i.e., the central portion of the light-emitting region 106a). As described above, the third oxidation confinement layer 110 and the fourth oxidation confinement layer 112 can not only limit the current but also inject a current into the central portion of the light emitting region 106a.

The fifth oxidation confinement layer 114, the sixth oxidation confinement layer 116, the seventh oxidation confinement layer 118, and the eighth oxidation confinement layer 120 of the VCSEL can be used to reduce parasitic capacitance. Oxidation of these layers equivalently increases the net dielectric thickness. The parasitic capacitance is generated by the oxidation confinement layer and the intrinsic semiconductor active region. They have no current, and the total capacitance is the sum of the oxidizing capacitances of these layers and the capacitances of the first to fourth oxidation limiting layers in series with the intrinsic semiconductor. The fifth to eighth oxidation confinement layers have an annular fifth current injection region 114a, a sixth current injection region 116a, a seventh current injection region 118a, and an eighth current injection region 120a, having a diameter of W3 (for example, 14 to 20 μm) in a central region thereof.

The p-type contact layer 122 is made of, for example, p-type GaAs. The p-side electrode 123 is formed by sequentially laminating, for example, a titanium (Ti) layer, a platinum (Pt) layer, and a gold (Au) layer, and is electrically connected to the p-type contact layer 122. Further, in the p-side electrode 123, the aperture W1 is provided in a region corresponding to the third current injection region 110a and the fourth current injection region 112a. The n-side electrode has a structure in which, for example, an alloy layer of gold (Au) and germanium (Ge), a nickel (Ni) layer and a gold (Au) layer are sequentially layered from the back of substrate 101. The n-side electrode 100 may be formed on the exposed surface around the mesa structure 130 in the n-type DBR layer 102, and electrically connected to the substrate 101.

Various other adaptations and combinations of features of the embodiments disclosed are within the scope of the disclosure. Accordingly, the present description should not be read as limiting the scope of the disclosure except as described in the claims that follow.

1. A vertical cavity surface emitting laser is characterized by comprising: a substrate (101), on which a bottom n-type DBR mirror (102), and a first oxidation confinement layer (104), a n-type guide spacer layer (105), an active region layer (106), a p-type guide spacer layer (107), a second oxidation confinement layer (108), a first spacer layer (109), a third oxidation confinement layer (110), a second spacer layer (111), a fourth oxidation confinement layer (112), a third spacer layer (113), a fifth oxidation confinement layer (114), a fourth spacer layer (115), a sixth oxidation confinement layer (116), a fifth spacer layer (117), a seventh oxidation confinement layer (118), a sixth spacer layer (119), an eighth oxidation confinement layer (120), a top p-type DBR mirror (121), a p-type contact layer (122) and a p-side electrode (123), an n-side electrode is disposed on a surface of the substrate (101);
a bottom n-type DBR mirror (102) includes a plurality of a first refractive index layers and a plurality of second refractive index layers,the first refractive index layers and the second refractive index layer are AlGaAs layers, the refractive index of the first refractive index layer is lower than that of the second refractive index layer;
the active region layer (106) is set at an antinode region of an optical standing wave formed by a vertical cavity surface emitting laser, the active region layer (106) includes a plurality of quantum well layers, the quantum well layer is an InAlGaAs layer;
the first oxidation confinement layer (104) have a first current injection region with the diameter in the range of 9-14 μm, the first oxidation confinement layer (104) is placed at the node of optical standing wave formed by the vertical cavity surface emitting laser;
the second oxidation confinement layer (108) have a second current injection region with the diameter which is equal to the diameter of the first current injection region, the second oxidation confinement layer (108) is placed at the node of optical standing wave formed by the vertical cavity surface emitting laser;
the third oxidation confinement layer (110) have a third current injection region with the diameter in the range of 6-9 μm which is smaller than the diameter of the second current injection region, the third oxidation confinement layer (110) is placed at the node of the optical standing wave formed by the vertical cavity surface emitting laser;
the fourth oxidation confinement layer (112) have a fourth current injection region with the diameter which is equal to the diameter of the third current injection region, the fourth oxidation confinement layer (112) is placed at the node of the optical standing wave formed by the vertical cavity surface emitting laser;
the fifth oxidation confinement layer (114) have a fifth current injection region with the diameter in the range of 14-20 μm, the fifth oxidation confinement layer (114) is placed at the node of the optical standing wave formed by the vertical cavity surface emitting laser;
the sixth oxidation confinement layer (116) have a sixth current injection region with the diameter in the range of 14-20 μm, the sixth oxidation confinement layer (116) is placed at the node of the optical standing wave formed by the vertical cavity surface emitting laser;
the seventh oxidation confinement layer (118) have a seventh current injection region with the diameter in the range of 14-20 μm, the seventh oxidation confinement layer (118) is placed at the node of the optical standing wave formed by the vertical cavity surface emitting laser;
the eighth oxidation confinement layer (120) have an eighth current injection region with the diameter in the range of 14-20 μm, the eighth oxidation confinement layer (120) is placed at the node of the optical standing wave formed by the vertical cavity surface emitting laser;
the top p-type DBR mirror (121) includes a plurality of third refractive index layers and a plurality of fourth refractive index layers, wherein the third refractive index layers and the fourth refractive index layers are all AlGaAs layers, the refractive index of the third refractive index layer is lower than that of the fourth refractive index layer;
the vertical cavity surface emitting laser further includes a mesa structure (130) extending from the top p-type DBR mirror (121) to the bottom n-type DBR mirror (102), and a dielectric coating layer being provided on at least a portion of the side of the mesa structure (130).

2. The vertical cavity surface emitting laser according to claim 1, wherein in at least one of the first oxidation confinement layer (104), the second oxidation confinement layer (108), the third oxidation confinement layer (110), the fourth oxidation confinement layer (112), the fifth oxidation confinement layer (114), the sixth oxidation confinement layer (116), the seventh oxidation confinement layer (118), and the eighth oxidation confinement layer (120) is provided with an first annular oxidation injection region, and the first annular oxidation injection region is provided with the current confinement layer that confines current flowing in the active region layer (106).

3. The vertical cavity surface emitting laser according to claim 1, wherein at least one of the first oxidation confinement layer (104), the second oxidation confinement layer (108), the third oxidation confinement layer (110), the fourth oxidation confinement layer (112), the fifth oxidation confinement layer (114), the sixth oxidation confinement layer (116), the seventh oxidation confinement layer (118), and the eighth oxidation confinement layer (120) is provided with a first annular oxidation confinement region, and the first annular oxidation confinement region is provided with the optical confinement layer that confines light generated in the active region layer (106).

4. The vertical cavity surface emitting laser according to claim 1, wherein at least four of the first oxidation confinement layer (104), the second oxidation confinement layer (108), the third oxidation confinement layer (110), the fourth oxidation confinement layer (112), the fifth oxidation confinement layer (114), the sixth oxidation confinement layer (116), the seventh oxidation confinement layer (118), and the eighth oxidation confinement layer (120) are provided with a second annular oxidation confinement region, and the second annular oxidation confinement region is provided with an oxide aperture.

5. The vertical cavity surface emitting laser according to claim 2 wherein the annular oxidation injection region, the first annular oxidation confinement region, and the second annular oxidation confinement region are oxidized AlGaAs layers having a composition of from 0.94 to 0.98.

6. The vertical cavity surface emitting laser according to claim 1, wherein the substrate (101) is a GaAs substrate (101).

7. The vertical cavity surface emitting laser according to claim 1, wherein further comprising a buffer layer between the substrate (101) and the bottom n-type DBR mirror (102).

8. The vertical cavity surface emitting laser according to claim 1, wherein the p-side electrode (123) is a ring electrode.

9. The vertical cavity surface emitting laser according to claim 1wherein the bottom -type DBR mirror (102), the active region layer (106) and the top p-type DBR mirror (121) are molecules beam epitaxial or metal organic chemical vapor deposition deposited layers.

10. The vertical cavity surface emitting laser according to claim 3, wherein the annular oxidation injection region, the first annular oxidation confinement region, and the second annular oxidation confinement region are oxidized AlGaAs layers having a composition of from 0.94 to 0.98.

11. The vertical cavity surface emitting laser according to claim 4, wherein the annular oxidation injection region, the first annular oxidation confinement region, and the second annular oxidation confinement region are oxidized AlGaAs layers having a composition of from 0.94 to 0.98.
